(19) United States
(12) Patent Application Publication
(10) Pub. No.: US 2024/0377481 A1
(43) Pub. Date: Nov. 14, 2024

(54) HALL ELEMENT

(71) Applicant: ROHM CO., LTD., Kyoto (JP)

(72) Inventors: Seiji YOSHIMUNE, Kyoto (JP); Hiroyuki YUJI, Kyoto (JP)

(73) Assignee: ROHM CO., LTD., Kyoto (JP)

(21) Appl. No.: 18/650,603

(22) Filed: Apr. 30, 2024

(30) Foreign Application Priority Data
May 8, 2023 (JP) 2023-076581

(51) Int. Cl. G01R 33/07; H10N 52/00; H10N 52/01; H10N 52/80

(52) U.S. Cl. CPC G01R 33/07; H10N 52/01; H10N 52/101; H10N 52/80

(57) ABSTRACT

A Hall element includes a first semiconductor layer that is conductive and defined on both faces by a first face and a second face opposed to each other, and a first magneto-sensitive layer and a second magneto-sensitive layer of a conductive semiconductor in a mesa shape. The first magneto-sensitive layer is arranged above a first face of a first semiconductor layer and has a bottom face opposed to the first face. The second magneto-sensitive layer is arranged in a position at a distance from the first magneto-sensitive layer above the first face and has a bottom face opposed to the first face.

### CROSS-REFERENCE TO RELATED APPLICATIONS

The present application is based on, and claims priority from Japanese Patent Application No. 2023-076581, filed on May 8, 2023, the entire contents of which are incorporated herein by reference.

### TECHNICAL FIELD

The present disclosure relates to a Hall element.

### BACKGROUND

A Hall element uses a Hall effect to detect a magnetic field. A planar Hall element is used to detect a magnetic field passing perpendicular to the substrate on which the Hall element is formed, and a vertical Hall element is used to detect a magnetic field passing parallel to the substrate. For example, as the vertical Hall element, an n-type semiconductor region in which a detection current flows for detecting a magnetic field is formed on a p-type silicon (Si) substrate.

### BRIEF DESCRIPTION OF DRAWINGS

FIG. 1 is a schematic cross-sectional view illustrating a structure of a Hall element according to a first embodiment.

FIG. 2 is a schematic perspective view illustrating an operation of the Hall element according to the first embodiment.

FIG. 3 is a schematic view illustrating prevention of erroneous detection of a magnetic field by the Hall element according to the first embodiment.

FIG. 4 is a schematic perspective view illustrating a structure of a magneto-sensitive layer model.

FIG. 5 is a schematic cross-sectional view illustrating another structure of the Hall element according to the first embodiment.

FIG. 6A is a schematic plan view illustrating a method of manufacturing the Hall element according to the first embodiment (Part 1).

FIG. 6B is a schematic cross-sectional view for explaining a method of manufacturing the Hall element according to the first embodiment (Part 1).

FIG. 7A is a schematic plan view for explaining a method of manufacturing a Hall element according to the first embodiment (Part 2).

FIG. 7B is a schematic cross-sectional view for explaining a method of manufacturing a Hall element according to the first embodiment (Part 2).

FIG. 8A is a schematic plan view for explaining a method of manufacturing a Hall element according to the first embodiment (Part 3).

FIG. 8B is a schematic cross-sectional view for explaining a method of manufacturing a Hall element according to the first embodiment (Part 3).

FIG. 9A is a schematic plan view for explaining a method of manufacturing a Hall element according to the first embodiment (Part 4).

FIG. 9B is a schematic cross-sectional view for explaining a method of manufacturing a Hall element according to the first embodiment (Part 4).

FIG. 10A is a schematic plan view for explaining a method of manufacturing a Hall element according to the first embodiment (Part 5).

FIG. 10B is a schematic cross-sectional view for explaining a method of manufacturing a Hall element according to the first embodiment (Part 5).

FIG. 11A is a schematic plan view for explaining a method of manufacturing a Hall element according to the first embodiment (Part 6).

FIG. 11B is a schematic cross-sectional view for explaining a method of manufacturing a Hall element according to the first embodiment (Part 6).

FIG. 12A is a schematic plan view for explaining a method of manufacturing a Hall element according to the first embodiment (Part 7).

FIG. 12B is a schematic cross-sectional view for explaining a method of manufacturing a Hall element according to the first embodiment (Part 7).

FIG. 13A is a schematic plan view for explaining a method of manufacturing a Hall element according to the first embodiment (Part 8).

FIG. 13B is a schematic cross-sectional view for explaining a method of manufacturing a Hall element according to the first embodiment (Part 8).

FIG. 14A is a schematic plan view for explaining a method of manufacturing a Hall element according to the first embodiment (Part 9).

FIG. 14B is a schematic cross-sectional view for explaining a method of manufacturing a Hall element according to the first embodiment (Part 9).

FIG. 15A is a schematic plan view for explaining a method of manufacturing a Hall element according to the first embodiment (Part 10).

FIG. 15B is a schematic cross-sectional view for explaining a method of manufacturing a Hall element according to the first embodiment (Part 10).

FIG. 16A is a schematic plan view for explaining a method of manufacturing a Hall element according to the first embodiment (Part 11).

FIG. 16B is a schematic cross-sectional view for explaining a method of manufacturing a Hall element according to the first embodiment (Part 11).

FIG. 17 is a schematic cross-sectional view illustrating an example of a shape of a magneto-sensitive layer of the Hall element according to the first embodiment.

FIG. 18 is a schematic diagram for explaining a spread of a detection current.

FIG. 19A is a schematic plan view illustrating a structure of a Hall element according to a modification of the first embodiment.

FIG. 19B is a schematic plan view illustrating another structure of the Hall element according to a modification of the first embodiment.

FIG. 20 is a schematic cross-sectional view illustrating a structure of a Hall element according to a second embodiment.

FIG. 21 is a schematic cross-sectional view for explaining a method of manufacturing the Hall element according to the second embodiment.

FIG. 22 is a schematic diagram for explaining an operation of a Hall element according to another embodiment.

### DETAILED DESCRIPTION

Embodiments will now be described with reference to the drawings. In the description of the following drawings, the same or similar parts are denoted by the same or similar reference numerals. However, it should be noted that the drawings are schematic, and the relationship between the thickness and the plane dimension, the ratio of the thickness of each part, and the like are different from the actual ones. In addition, it should be noted that the drawings include parts whose relationship or ratio of each other's dimensions is different.

In addition, the following embodiments illustrate an apparatus or method for embodying technical ideas, and do not specify the shape, structure, arrangement, and the like of the components as follows. Various modifications may be made to this embodiment within the scope of claims.

### First Embodiment

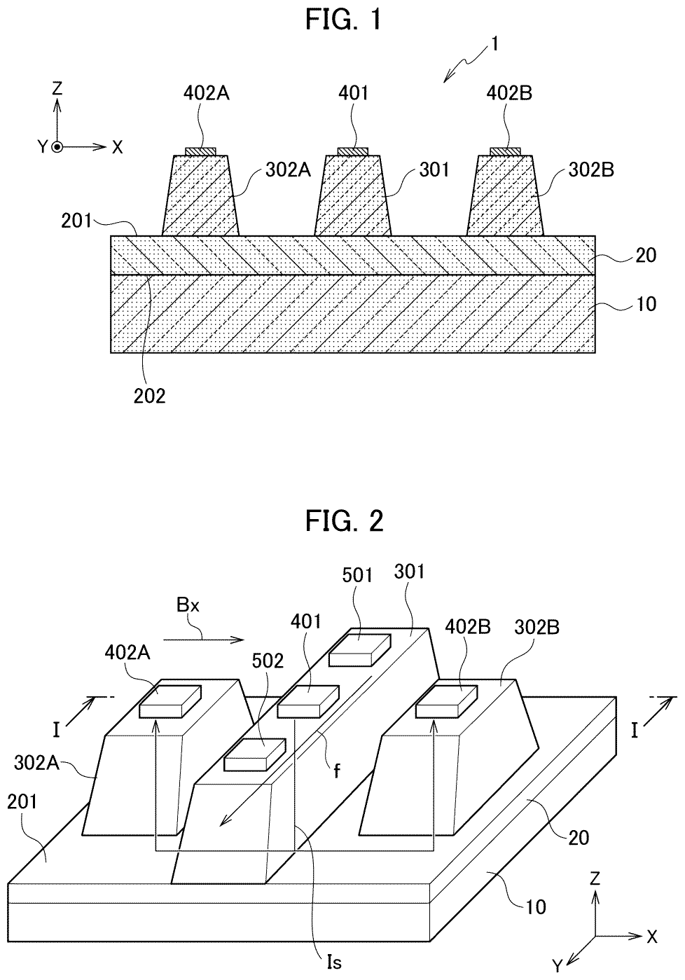

As illustrated in FIG. 1, a Hall element 1 according to a first embodiment includes a first semiconductor layer 20 defined on both faces by a first face 201 and a second face 202 opposed to each other, and a first magneto-sensitive layer 301 and second magneto-sensitive layers 302A, 302B arranged above the first face 201. Hereafter, the second magneto-sensitive layer 302A and the second magneto-sensitive layer 302B are referred to as the “second magneto-sensitive layer 302” if they are not limited to each other. The second magneto-sensitive layer 302 is arranged in a position at a distance from the first magneto-sensitive layer 301 above the first face 201. The first magneto-sensitive layer 301 and the second magneto-sensitive layer 302 are referred to as a “magneto-sensitive layer 30” if they are not limited to each other. The magneto-sensitive layer 30 and the first semiconductor layer 20 are electrically connected.

The magneto-sensitive layer 30 has a mesa shape with a bottom face opposed to the first face 201 and a side face extending in a direction intersecting the first face 201. The side face of the magneto-sensitive layer 30 illustrated in FIG. 1 is exposed. The direction from the bottom face of the magneto-sensitive layer 30 to a top face opposed to the bottom face intersects the first face 201. For example, the direction from the bottom face to the top face of the magneto-sensitive layer 30 may be perpendicular to the first face 201.

The materials of the first semiconductor layer 20 and the magneto-sensitive layer 30 are conductive semiconductors. For example, the materials of the first semiconductor layer 20 and the magneto-sensitive layer 30 may be Si semiconductors or compound semiconductors such as GaAs, InP, InSb, and AlGaAs. Hereinafter, a case in which the materials of the first semiconductor layer 20 and the magneto-sensitive layer 30 include GaAs will be described by way of example.

As illustrated in FIG. 1, a thickness direction of the first semiconductor layer 20 (a direction from the second face 202 to the first face 201) is a Z direction. In FIG. 1, the Z direction is a vertical direction to the paper surface. A plane perpendicular to the Z direction is an XY plane defined by the X and Y directions. In FIG. 1, the X direction is left and right directions of the paper, and the Y direction is a depth direction of the paper. In this disclosure, in the Z direction, a direction in which the magneto-sensitive layer 30 is located as viewed from the first semiconductor layer 20 is an upward direction, and a direction in which the first semiconductor layer 20 is located as viewed from the magneto-sensitive layer 30 is a downward direction. For each layer of the Hall element 1, a face oriented upward is also referred to as an upper face, and a face oriented downward is referred to as a lower face or a bottom face. For example, the first face 201 is the upper face of the first semiconductor layer 20, and the second face 202 is the lower face of the first semiconductor layer 20.

The Hall element 1 illustrated in FIG. 1 has a configuration in which two second magneto-sensitive layers 302 are arranged across the first magneto-sensitive layer 301. In other words, the second magneto-sensitive layer 302A, the first magneto-sensitive layer 301, and the second magneto-sensitive layer 302B are arranged in this order in the X direction.

The first semiconductor layer 20 may be, for example, a GaAs semiconductor layer doped with an n-type impurity. The impurity concentration of the first semiconductor layer 20 is, for example, 1E17 cm⁻³ to 1E19 cm⁻³. The magneto-sensitive layer 30 may be, for example, a GaAs semiconductor layer doped with an n-type impurity. The impurity concentration of the magneto-sensitive layer 30 is, for example, 1E16 cm⁻³ to 1E17 cm⁻³. The n-type impurity may be, for example, Si, Te, Zn, Mg, or Be.

The Hall element 1 illustrated in FIG. 1 further includes a substrate 10 connected to the second face 202 of the first semiconductor layer 20. For example, a semi-insulating substrate or an insulating substrate may be used for the substrate 10. The substrate 10 may be, for example, a GaAs substrate, an InP substrate, an InSb substrate, a Si substrate, or the like.

As illustrated in FIG. 1, the Hall element 1 includes a first main electrode 401 arranged on the upper face of the first magneto-sensitive layer 301, a second main electrode 402A arranged on the upper face of the second magneto-sensitive layer 302A, and a second main electrode 402B arranged on the upper face of the second magneto-sensitive layer 302B. Hereinafter, the second main electrode 402A and the second main electrode 402B are referred to as the “second main electrode 402” if they are not limited to each other. The first main electrode 401 and the second main electrode 402 are referred to as the “main electrode 40” if they are not limited to each other. The material of the main electrode 40 may be, for example, Au, AuGe/Ni, Ti/Au, Ti/Pt/Au, or the like.

The first main electrode 401 is a first end of a current path of a detection current Is flowing between the first magneto-sensitive layer 301 and the second magneto-sensitive layer 302 via the first semiconductor layer 20. The second main electrode 402 is a second end of the current path of the detection current Is. Hereinafter, a case in which a detection current Is flows from the first magneto-sensitive layer 301 to the second magneto-sensitive layer 302 will be described by way of example. For example, a power source for passing the detection current Is from the first main electrode 401 to the second main electrode 402 is provided outside the Hall element 1.

In the Hall element 1, the detection current Is flowing between the first main electrode 401 and the second main electrode 402 flows in the Z direction, which is a surface normal direction of the first face 201 of the first semiconductor layer 20 in the first magneto-sensitive layer 301 and the second magneto-sensitive layer 302. In other words, the detection current Is flows in the direction perpendicular to the main face of the substrate 10. Since the detection current Is flows in the direction perpendicular to the main face of the substrate 10, the Hall element 1 can detect the magnetic field in a direction parallel to the main surface of the substrate 10, as described later.

The Hall element 1 further includes a pair of a first Hall electrode 501 and a second Hall electrode 502 arranged on the upper face of the first magneto-sensitive layer 301 across the first main electrode 401. Hereafter, the first Hall electrode 501 and the second Hall electrode 502 are referred to as a “Hall electrodes 50” if they are not limited to each other. The materials of the Hall electrode 50 are the same as those of the main electrode 40.

A Lorentz force is generated in the Hall element 1 by a magnetic field in a direction parallel to the first face 201 of the first semiconductor layer 20 and a detection current Is flowing through the magneto-sensitive layer 30 in a direction perpendicular to the first face 201. As described below, the Hall element 1 detects a Hall output voltage due to the Lorentz force by the Hall electrode 50.

An operation example of the Hall element 1 will be described below with reference to FIG. 2. In FIG. 2, the first semiconductor layer 20 is displayed by passing through the magneto-sensitive layer 30, and the side face of the magneto-sensitive layer 30 is described perpendicularly to the first face 201 of the first semiconductor layer 20.

In order to detect the magnetic field by the Hall element 1, a detection current Is flows between the first main electrode 401 and the second main electrode 402 through the first semiconductor layer 20. As described above, the detection current Is flows through the magneto-sensitive layer 30 in a direction perpendicular to the first face 201 of the first semiconductor layer 20 and through the first semiconductor layer 20 in a direction parallel to the first face 201. The electrical insulation of the substrate 10 with respect to the first semiconductor layer 20 is ensured so that the detection current Is does not flow through the substrate 10.

The Lorentz force f is generated by the detection current Is and the magnetic field Bx according to Fleming's left-hand rule when the magnetic field Bx passes in the direction parallel to the main surface of the substrate 10 while the detection current Is flows through the magneto-sensitive layer 30 in the direction perpendicular to the first face 201. Charged particles (carriers) accumulate at the destination of the Lorentz force f, and the Hall output voltage is generated by the unbalanced charged particles.

In the Hall element 1, the Hall output voltage generated due to the Lorentz force f from the first Hall electrode 501 to the second Hall electrode 502 is detected by the Hall electrode 50. As described above, the magnetic field Bx is detected by the Hall element 1.

In the Hall element 1, respective second magneto-sensitive layers 302 are arranged on both sides of the first magneto-sensitive layer 301. Therefore, the detection current Is is divided into a component flowing through the second magneto-sensitive layer 302A and a component flowing through the second magneto-sensitive layer 302B after flowing through the first magneto-sensitive layer 301. In other words, in the Hall element 1, a current path from the first magneto-sensitive layer 301 to the second magneto-sensitive layer 302A via the first semiconductor layer 20 and a current path from the first magneto-sensitive layer 301 to the second magneto-sensitive layer 302B via the first semiconductor layer 20 are formed.

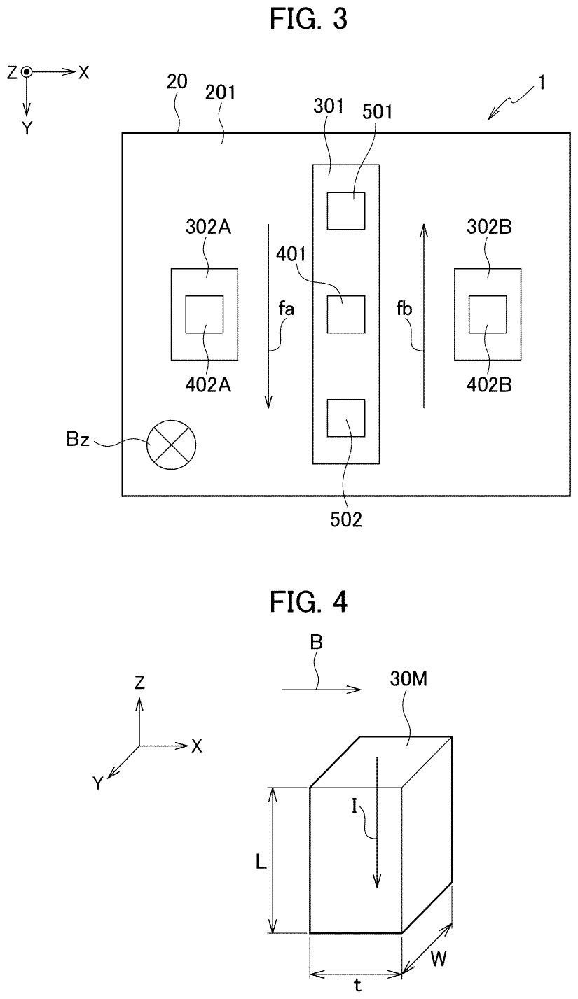

The presence of two current paths of the detection current Is prevents the Hall element 1 from erroneously detecting a magnetic field (Hereinafter also referred to as “vertical magnetic field”.) passing in the direction perpendicular to the main face of the substrate 10. For example, as illustrated in FIG. 3, a Lorentz force fa for the component flowing in the second sensitive layer 302A of the detection current Is and a Lorentz force fb for the component flowing in the second sensitive layer 302B of the detection current Is are generated when the magnetic field Bz passes in the direction perpendicular to the first face 201. At this time, as illustrated in FIG. 3, the directions of the Lorentz force fa and the Lorentz force fb are opposite. Therefore, the directions of the Hall output voltage due to the Lorentz force fa and the Lorentz force fb are symmetrical, so that the Hall output voltage is not generated by cancelling each other. Therefore, only the magnetic field Bx passing in the direction parallel to the main surface of the substrate 10 is detected by the Hall element 1.

In order to increase the sensitivity of the Hall element 1, it is effective to increase the distance for which the detection current Is flows in the magneto-sensitive layer 30. In other words, it is effective to increase the film thickness of the magneto-sensitive layer 30 in order to increase the sensitivity. The film thickness of the magneto-sensitive layer 30 is a length from the top face to the bottom face along the surface normal direction (Z direction) of the first face 201 of the first semiconductor layer 20.

However, there is a limit to increasing the film thickness of the magneto-sensitive layer 30 when the semiconductor film is etched into a mesa shape to form the magneto-sensitive layer 30 as described later. This is because the film thickness of the magneto-sensitive layer 30 is limited by the film forming apparatus. For example, an upper limit of a growing film thickness exists in an epitaxial growth apparatus when the magneto-sensitive layer 30 is formed by an epitaxial growth method. Therefore, it is preferable to increase the sensitivity of the Hall element 1 by a method other than increasing the film thickness of the magneto-sensitive layer 30.

The sensitivity of the Hall element 1 will be discussed below with reference to a magneto-sensitive layer model 30M illustrated in FIG. 4. The size of the magneto-sensitive layer model 30M is as follows: a thickness L along the Z direction in which the current I flows, a length t along the X direction in which the magnetic field B is directed, and a width W along the Y direction perpendicular to the thickness L and the length t. The thickness L corresponds to the film thickness of the magneto-sensitive layer 30. The length t and the width W depend on the size of the main electrode 40.

When a current I and a magnetic field B are applied to the magneto-sensitive layer model 30M, the carrier receives a Lorentz force of f=q×v×B. Character q is charge of the electron and v is drift velocity. The steady state is reached when the Lorentz force f is balanced with the force F from the electric field caused by the carrier unbalance due to the Lorentz force f. The force F from the electric field is expressed by the following formula (1):

$$F = q \times ( V h / W ) . \qquad ( 1 )$$

In formula (1), Vh is a Hall output voltage. On the other hand, the current I is expressed by formula (2):

$$I = q \times n \times v \times W \times t . \qquad ( 2 )$$

In formula (2), n is carrier concentration.

When the drift velocity v in formula (2) is removed from f-F to drive the magneto-sensitive layer model 30M at constant current, the Hall output voltage Vh is expressed by formula (3) below:

$$V h = I \times B / ( q \times n \times t ) . \qquad ( 3 )$$

When the Hall element is driven at constant voltage, the Hall output voltage Vh is expressed by formula (4) obtained by substituting into equation (3) the input voltage Vin=Rs×(L/W)×I when the sheet resistance of the magneto-sensitive layer model 30M is set to Rs:

$$V h = μ \times ( W / L ) \times V in \times B . \qquad ( 4 )$$

In formula (4), μ is the mobility of the carrier. Here, the sheet resistance is Rs=1/(q×n×μ×t).

Sensitivity Kh of the sensitive layer model 30M is expressed by the following formula (5) using a resistivity ρ:

$$Kh = 1 / ( q \times n \times t ) = Rs \times μ = ρ \times μ / t . \qquad ( 5 )$$

The sensitivity Kh when the thickness L is short with respect to the width W of the sensitive layer 30 is expressed by the formula (6) obtained by multiplying the sensitivity Kh represented in formula (5) by the shape effect coefficient K:

$$Kh = 1 / ( q \times n \times t ) \times K . \qquad ( 6 )$$

For example, K=1 for L>>W and K=0.74×L/W for L<W.

The length t and the width W depend on the size of the main electrode 40, and the thickness L corresponds to the film thickness of the magneto-sensitive layer 30. In the Hall element 1 having a shorter thickness L, it is preferable that the sensitivity Kh is not multiplied by the shape effect coefficient K. The improvement of the sensitivity Kh of the Hall element 1 will be discussed below.

Formula (5) represents that to increase the sensitivity Kh, the carrier concentration n and the length t should be reduced. Therefore, it is effective to reduce the carrier concentration n by use of Si as the material of the sensitive layer 30 in order to increase the sensitivity Kh.

On the other hand, the length t of compound semiconductors such as GaAs can be reduced because the mobility u is higher than that of Si. Therefore, the length t may be reduced and the sensitivity Kh may be increased by using compound a semiconductor as a material for the magneto-sensitive layer 30. For example, the length t may be reduced to increase the sensitivity Kh when the resistance value of the magneto-sensitive layer 30 is fixed.

Since the sensitivity Kh has a dependence on the carrier concentration n, a Hall element 1 whose sensitivity varies little with temperature can be obtained by using a compound semiconductor in the magneto-sensitive layer 30. Further, a Hall element 1 having a resistance value and temperature characteristics equivalent to those of a planar Hall element using a compound semiconductor may be realized by using a compound semiconductor having a lower resistance value than Si in the magneto-sensitive layer 30.

In order to increase the sensitivity of the magneto-sensitive layer model 30M, it is effective to reduce the length t and set L≥W. For example, the sensitivity of the magneto-sensitive layer model 30M can be increased by increasing the thickness L and decreasing the width W.

As described above, the Hall element 1 according to the first embodiment can provide a Hall element having a magneto-sensitive layer 30 in a mesa shape. By forming a magneto-sensitive layer 30 in a mesa shape, it is easy to construct a Hall element using materials with which it is difficult to form a magneto-sensitive layer as an embedded region in a semiconductor substrate or semiconductor layer. In addition, generation of leakage current and floating capacitance is suppressed in the Hall element 1 in comparison with the Hall element in which the p-type semiconductor region and the n-type semiconductor region are adjacent, for example. Therefore, the Hall element 1 can detect the magnetic field with high accuracy.

In the process of etching a semiconductor film to form the magneto-sensitive layer 30 in a mesa shape, there is a possibility that the semiconductor film remains on the first face 201 of the first semiconductor layer 20 in the remaining region excluding the region in which the magneto-sensitive layer 30 is formed. If the semiconductor film remains on the first face 201 of the first semiconductor layer 20, a portion of the detection current Is may flow between the first magneto-sensitive layer 301 and the second magneto-sensitive layer 302 through the semiconductor film. When the detection current Is flows through the semiconductor film, the sensitivity of the Hall element 1 decreases due to an increase of the resistance value of the detection current Is flowing in parallel with the first face 201 of the first semiconductor layer 20, detection of the perpendicular magnetic field, and the like.

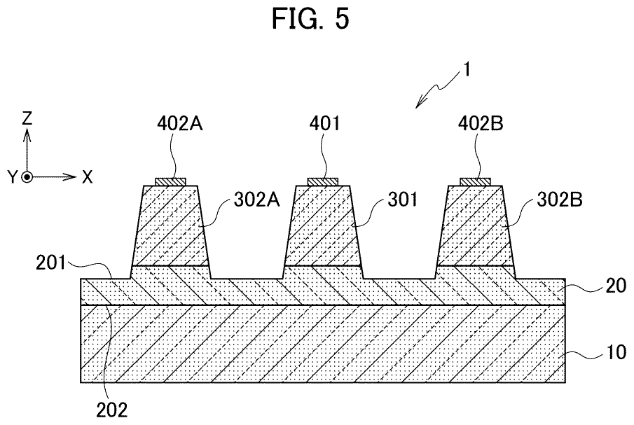

Therefore, as illustrated in FIG. 5, the magneto-sensitive layer 30 may be formed by over-etching a top part of the first face 201 of the first semiconductor layer 20. By over-etching, the semiconductor film does not remain in the remaining area of the first face 201 except the area in contact with the magneto-sensitive layer 30 in a mesa shape.

In the Hall element 1 illustrated in FIG. 5, by forming the magneto-sensitive layer 30 by over-etching, the area in contact with the bottom face of the magneto-sensitive layer 30 of the first semiconductor layer 20 is not etched and a protrusion portion is formed. Therefore, the Hall element 1 has a configuration in which the first magneto-sensitive layer 301 and the second magneto-sensitive layer 302 are arranged on a top face of a protrusion portion formed on the first face 201 of the first semiconductor layer 20.

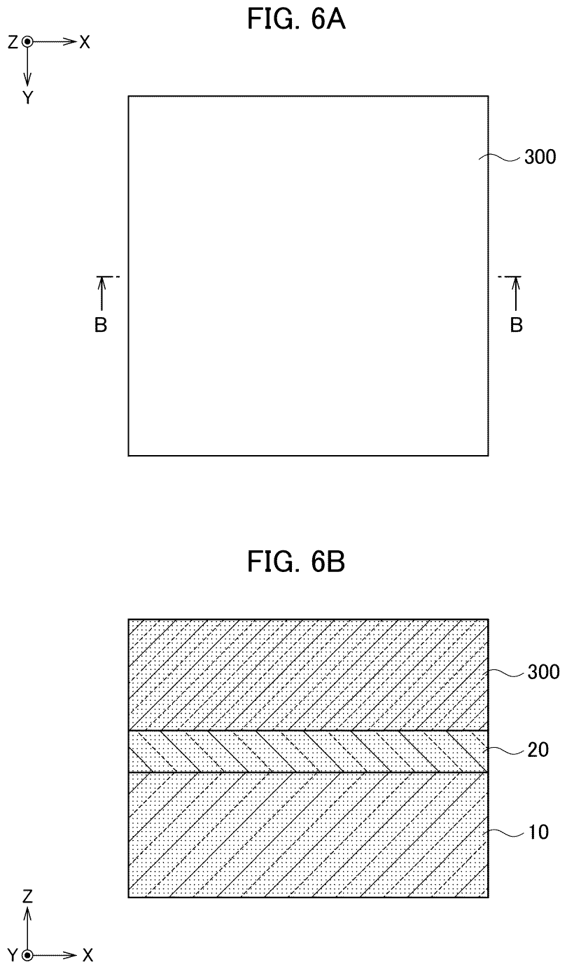

Hereinafter, a manufacturing method of the Hall element 1 according to the first embodiment will be described with reference to FIGS. 6A and 6B to 16A and 16B. FIGS. 6A to 16A are plan views in the Z direction, and FIGS. 6B to 16B are cross-sectional views in the B-B direction of FIGS. 6A to 16A. The manufacturing method of the Hall element 1 described below is an example, and can be realized by various other manufacturing methods including this modification. In the following, a case in which the magneto-sensitive layer 30 is formed by over-etching described with reference to FIG. 5 will be described.

First, as illustrated in FIGS. 6A and 6B, the first semiconductor layer 20 and the magneto-sensitive layer film 300 are sequentially formed on the main face of the substrate 10 by, for example, an epitaxial growth method. For example, a GaAs (n⁺-GaAs) layer doped with an n-type impurity is formed as the first semiconductor layer 20 on the main face of the substrate 10 of the GaAs substrate. Then, a GaAs (n-GaAs) film doped with an n-type impurity is formed as the magneto-sensitive layer film 300 on the upper face (first face 201) of the first semiconductor layer 20. The n-type impurity is, for example, Si. The impurity concentration of the first semiconductor layer 20 is, for example, 1E17 cm⁻³ to 1E19 cm⁻³, and the film thickness is, for example, about 1 to 5 μm. The impurity concentration of the magneto-sensitive layer film 300 is, for example, 1E16 cm⁻³ to 1E17 cm⁻³, and the film thickness is, for example, about 15 μm.

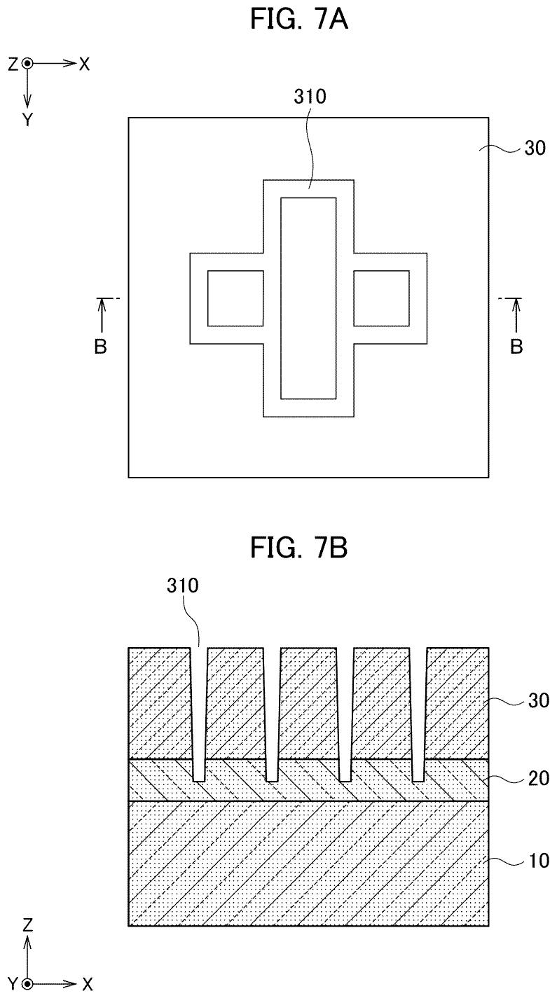

Next, as illustrated in FIGS. 7A and 7B, a part of the magneto-sensitive layer film 300 is selectively etched away to form the magneto-sensitive layers 30. At this time, as illustrated in FIG. 7B, a part of the upper part of the first semiconductor layer 20 is etched from the first face 201 by forming a groove (hereinafter referred to as “mesa groove 310”.) between the mesa shapes by over-etching. A dry etching method such as reactive ion etching (RIE) may be used for etching of the magneto-sensitive layer film 300.

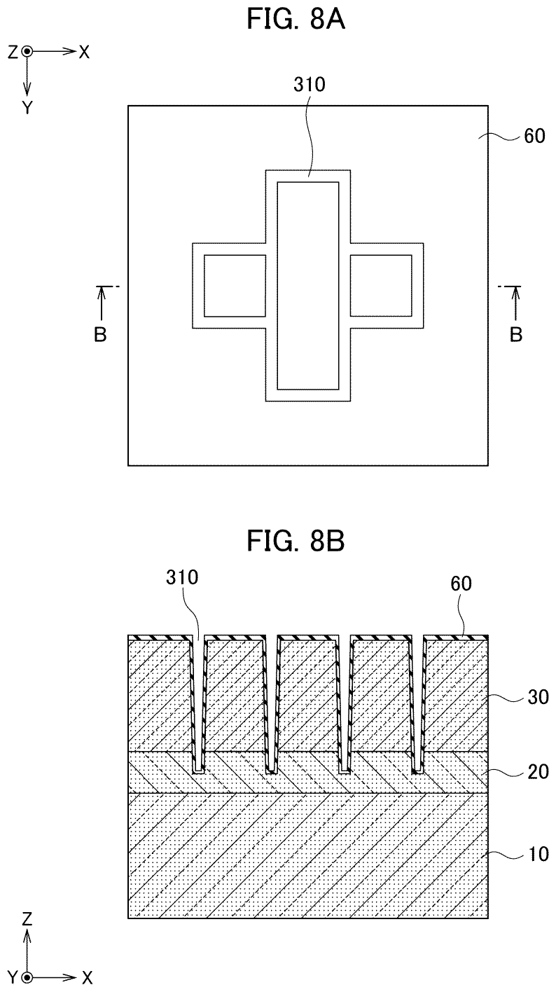

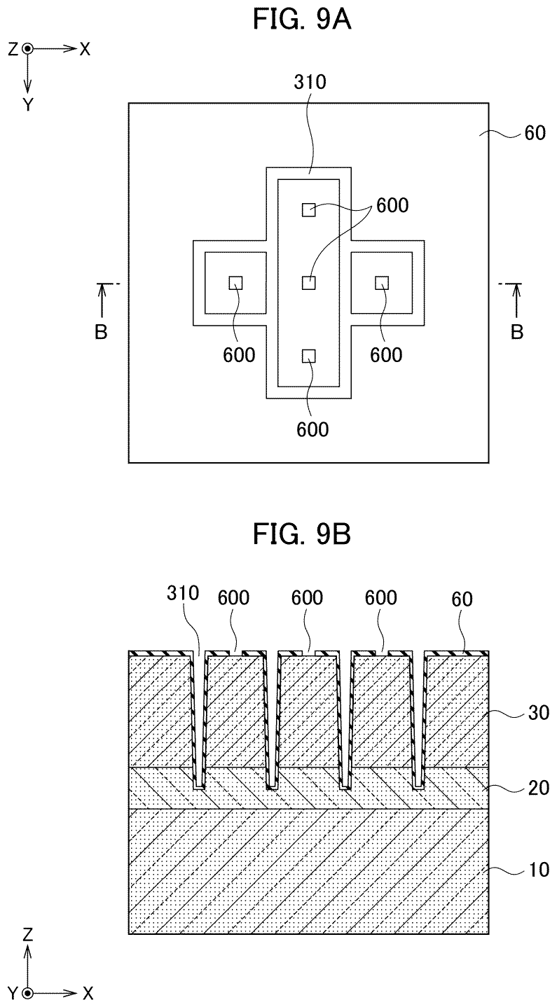

After forming the magneto-sensitive layers 30, an insulating film 60 is formed on the upper face of the magneto-sensitive layers 30 as illustrated in FIGS. 8A and 8B. The insulating film 60 may be, for example, a silicon nitride film. Thereafter, as illustrated in FIGS. 9A and 9B, parts of the insulating film 60 are removed in regions in which the main electrodes 40 and the Hall electrodes 50 are arranged. For example, openings 600 are provided in the insulating film 60 by a photolithography technique and a dry etching method.

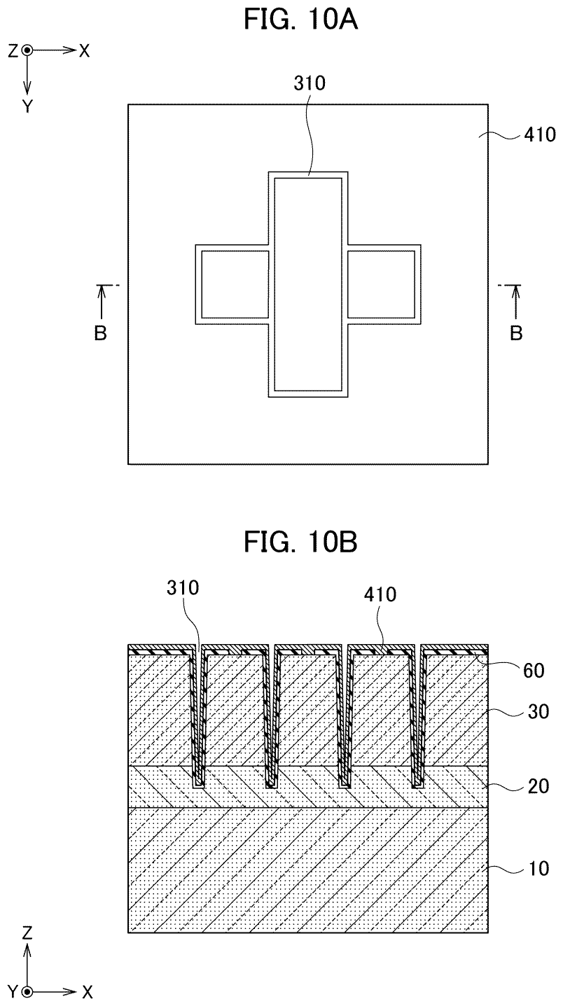

Thereafter, as illustrated in FIGS. 10A and 10B, a first metal film 410 is formed on an upper face of the insulating film 60 by burying each opening 600 of the insulating film 60. At this time, the first metal film 410 is also formed on a wall face of the mesa groove 310. For example, the first metal film 410 may be formed by sequentially stacking the AuGe film and the Ni film.

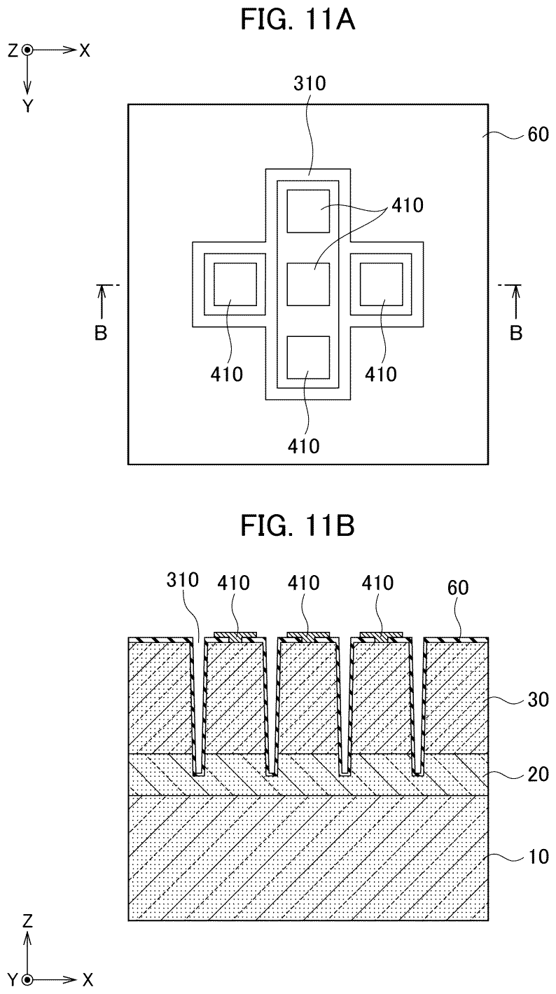

After the first metal film 410 is formed, as illustrated in FIGS. 11A and 11B, the first metal film 410 is selectively removed so that only the regions of the main electrodes 40 and the Hall electrodes 50 remain. Laminated films of an AuGe film and Ni film can then be alloyed by heat treatment to form an AuGe/Ni film.

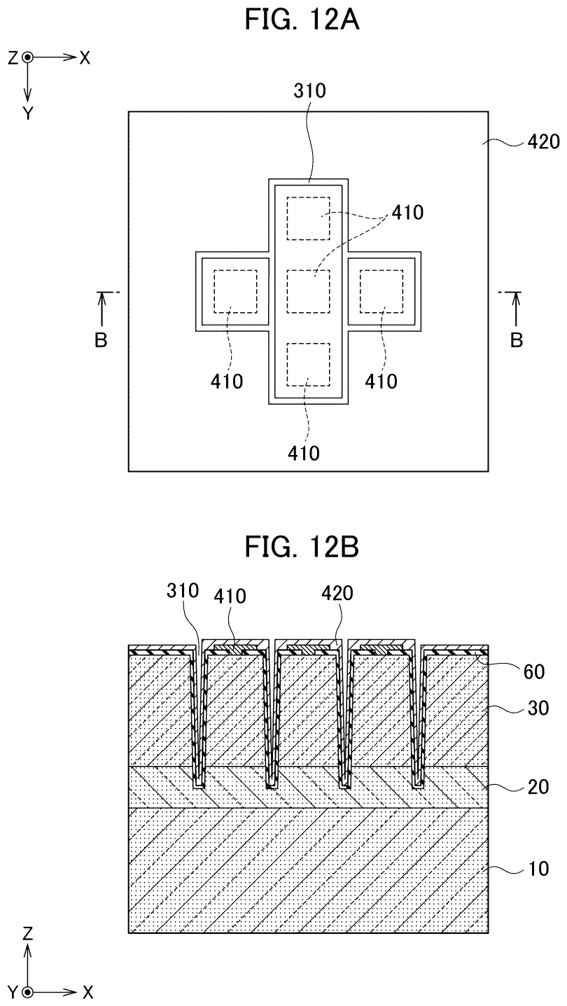

Next, as illustrated in FIGS. 12A and 12B, a second metal film 420 is formed on an upper face of the insulating film 60 and the wall face of the mesa groove 310 so as to cover the upper face of the first metal film 410. The second metal film 420 may be, for example, a TiAu film.

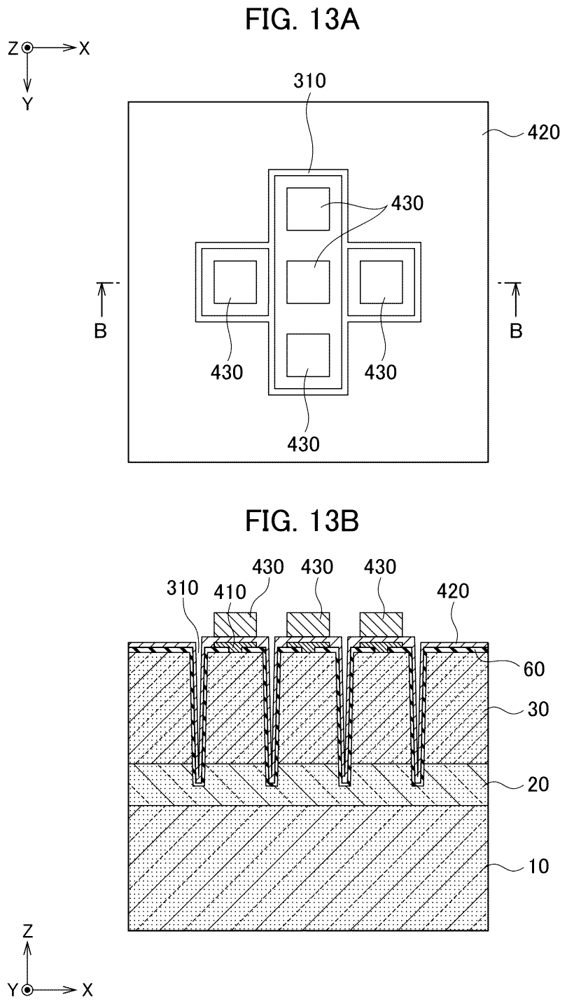

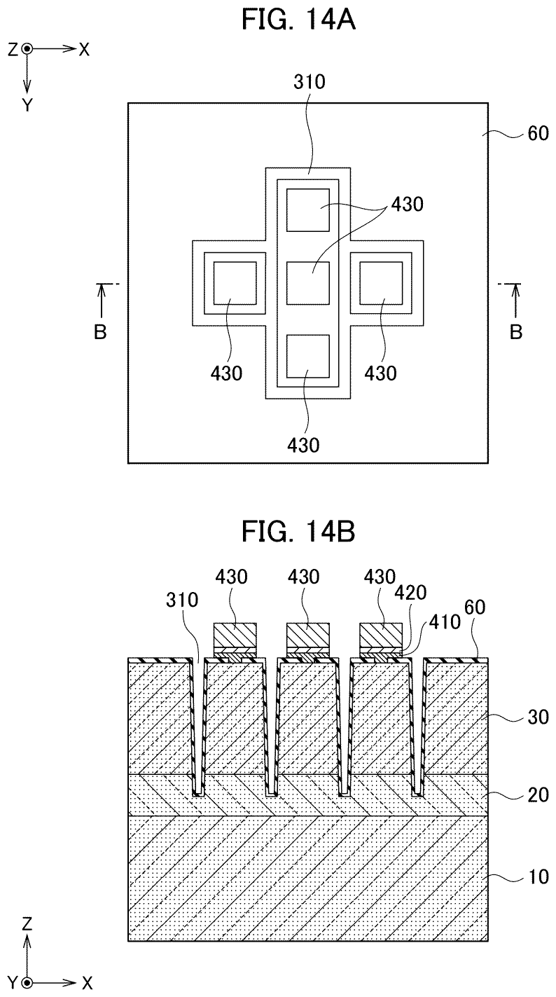

Next, as illustrated in FIGS. 13A and 13B, third metal films 430 are formed on an upper face of the second metal film 420 above the first metal films 410. The third metal films 430 may be, for example, Au plated. Thereafter, as illustrated in FIGS. 14A and 14B, the second metal film 420 is selectively removed except for the regions of the main electrodes 40 and the Hall electrodes 50. By the process described above, for example, the main electrodes 40 and the Hall electrodes 50 each having a laminated structure of the AuGe/Ni film, the TiAu film, and the Au plating are formed.

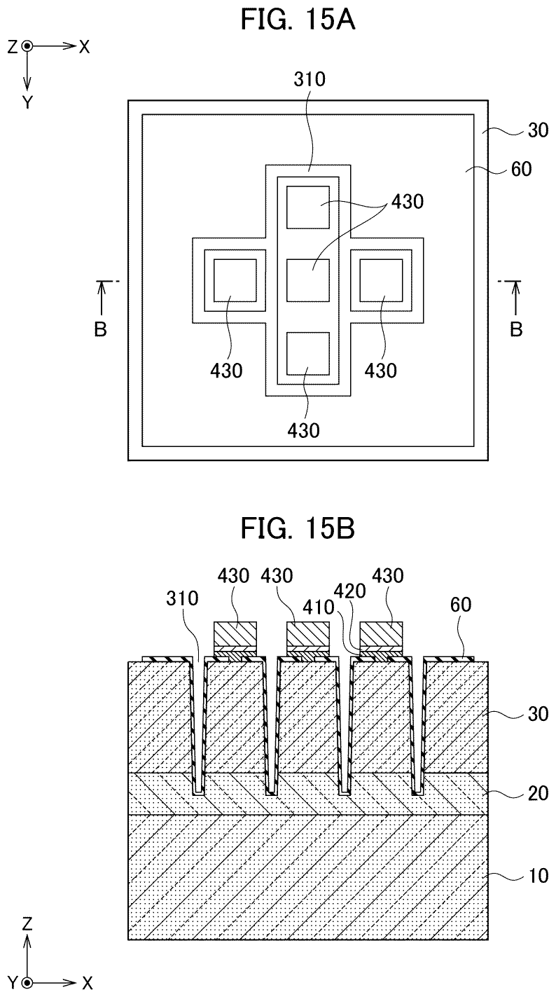

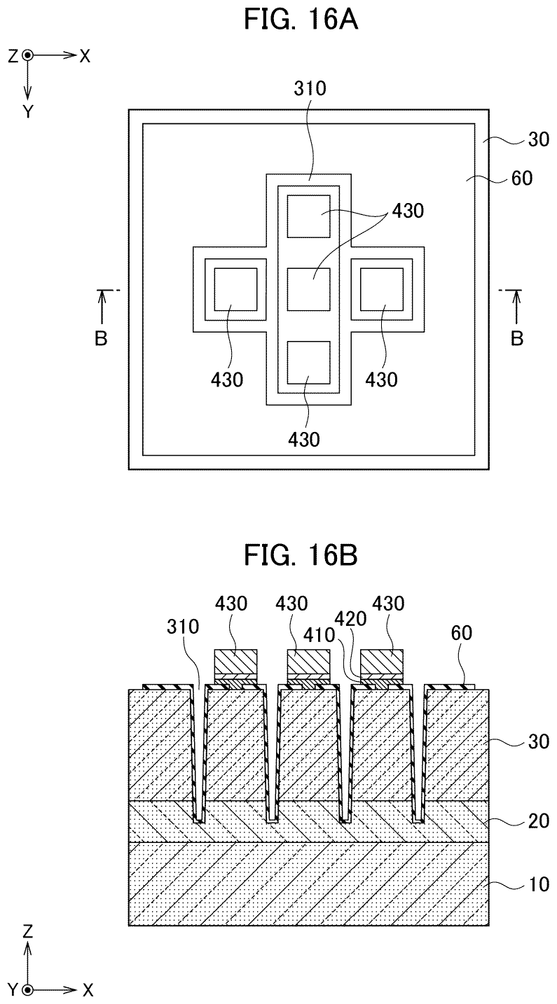

Thereafter, as illustrated in FIGS. 15A and 15B, the insulating film 60 of a dicing street which is an outer edge of the Hall element 1 is removed. Next, as illustrated in FIGS. 16A and 16B, a back face lapping is performed to polish the lower surface of the substrate 10.

By the processes described above, the Hall element 1 is completed in which respective bottom faces of first magneto-sensitive layer 301 and the second magneto-sensitive layers 302 in mesa shapes contact with the first face 201 of the first semiconductor layer 20. The electrical resistance of the detection current Is flowing in the direction perpendicular to the first face 201 of the first semiconductor layer 20 can be reduced since the first magneto-sensitive layer 301 and the second magneto-sensitive layers 302 are in direct contact with the first semiconductor layer 20.

Carrier mobility of an n-type semiconductor implanted with an n-type impurity can be higher than that of a p-type semiconductor implanted with a p-type impurity. Therefore, in the Hall element 1, it is preferable to use an n-type impurity as an impurity of the semiconductor in order to increase the sensitivity of the magnetic field. The detection current Is flowing parallel to the first face 201 does not directly participate in the detection of the magnetic field B. Therefore, in order to reduce the electrical resistance of the detection current Is flowing parallel to the first face 201, the impurity concentration of the first semiconductor layer 20 is set higher than the impurity concentration of the magneto-sensitive layer 30.

As described above, the perpendicular magnetic field is prevented from being detected erroneously since the directions of the Lorentz force f generated for the components flowing in the second magneto-sensitive layer 302A and the components flowing in the second magneto-sensitive layer 302B of the detection current Is are opposite. Therefore, in order to make the components of the detection current Is flowing in the second magneto-sensitive layer 302A and the second magneto-sensitive layer 302B equal, it is preferable that the electric resistance of the current path in the second magneto-sensitive layer 302A and the current path in the second magneto-sensitive layer 302B are equal.

Therefore, the magneto-sensitive layer 30 is formed so that the height and the cross-sectional area of the second magneto-sensitive layer 302A and the second magneto-sensitive layer 302B are equal. The height of the magneto-sensitive layer 30 is the size in the direction perpendicular to the first face 201 of the first semiconductor layer 20, and the cross-sectional area is the area of the cross-section perpendicular to the height direction. Furthermore, other mesa shape parameters that affect the electrical resistance of the second magneto-sensitive layer 302, such as the inclination of the side surface with respect to the first face 201 and the widths of the bottom face and the top face, are preferably equal between the second magneto-sensitive layer 302A and the second magneto-sensitive layer 302B.

In forming the magneto-sensitive layer 30, for example, a silicon oxide film or a photoresist film patterned by photolithography may be used as an etching mask. The stability of the shape of the etching mask can be improved by using a silicon oxide film or the like, which has higher hardness than the photoresist film, as an etching mask.

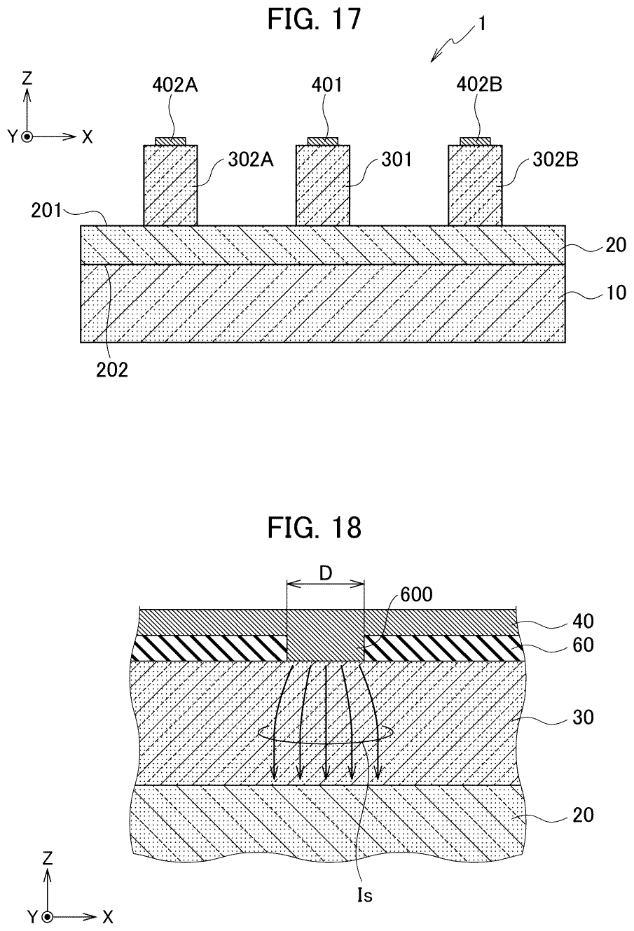

Each side face of the magneto-sensitive layer 30 may extend in a direction perpendicular to the first face 201 of the first semiconductor layer 20 or in a direction obliquely intersecting the first face 201. For example, as illustrated in FIG. 17, the size of the Hall element 1 can be reduced viewing from the Z direction by the side face of the magneto-sensitive layer 30 extending perpendicular to the first face 201 of the first semiconductor layer 20.

As represented in formulae (5) and (6), the sensitivity Kh depends on the length t and the width W of the magneto-sensitive layer 30 along the direction of the magnetic field. Therefore, the size of the magneto-sensitive layer 30 may be set according to the sensitivity required for the Hall element 1. However, as illustrated in FIG. 18, the detection current Is flowing from the main electrode 40 to the magneto-sensitive layer 30 spreads in a transverse direction (XY plane) inside the magneto-sensitive layer 30 while flowing in the vertical direction (Z direction). Accordingly, the size of the main electrode 40 is preferably smaller than the area of the upper face of the magneto-sensitive layer 30. For example, the length of one side of the magneto-sensitive layer 30 is set to be about three times the length of the corresponding side of the main electrode 40. Therefore, the size of the main electrode 40 is preferably set in consideration of the spread of the detection current Is with respect to the size of the magneto-sensitive layer 30 in accordance with the required sensitivity.

The size of the main electrode 40 is limited by a lower limit of a manufacturing limit in an electrode process design. Moreover, in order to electrically connect the main electrode 40 to an external power source, for example, by wire bonding, a certain area is required for the main electrode 40. Therefore, as illustrated in FIG. 18, the main electrode 40 having the required area is formed on the upper face of the insulating film 60 formed on the upper face of the magneto-sensitive layer 30, and the main electrode 40 and the magneto-sensitive layer 30 are brought into contact with each other in the opening 600 of the insulating film 60. In other words, the size (hereinafter referred to as “thirling size D”) of the opening 600 of the insulating film 60 is designed to correspond to the size of the magneto-sensitive layer 30 according to the required sensitivity.

As described above, the insulating film 60 is preferably formed on the upper face of the magneto-sensitive layer 30, and the main electrode 40 is preferably electrically connected to the magneto-sensitive layer 30 through the opening 600 provided in the insulating film 60. The thirling size D of the opening 600 of the insulating film 60 is preferably set in consideration of the size of the magneto-sensitive layer 30 which affects the sensitivity Kh of the Hall element 1, the spread of the detection current Is in the magneto-sensitive layer 30, the relationship between the size of the main electrode 40 and the thirling size D. The thirling size D is substantially the size of the main electrode 40 of the Hall element 1 which affects the sensitivity Kh.

### Modification

In the description above, a pair of second magneto-sensitive layers 302 is arranged across the first magneto-sensitive layer 301. As described above, it is preferable that the current path of the detection current Is is composed of two current paths symmetrically along the passing direction of the magnetic field Bx so as not to detect the vertical magnetic field erroneously. Therefore, the detection current Is may be branched into two or more plural parts while maintaining symmetry with respect to the first magneto-sensitive layer 301. In other words, the number of the second magneto-sensitive layer 302 may be other than two if symmetry of the detection current Is is maintained.

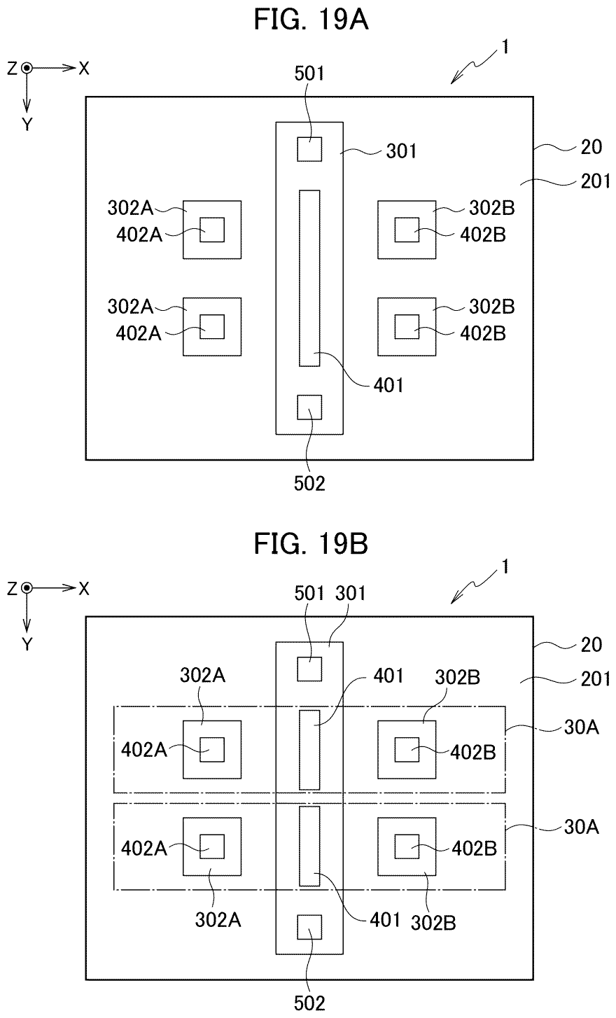

For example, as illustrated in FIG. 19A, there may be a plurality of pairs of second magneto-sensitive layers 302 arranged on both sides of the first magneto-sensitive layer 301. Alternatively, as illustrated in FIG. 19B, there may be a plurality of electromagnetic layer units 30A having a configuration in which a pair of second magneto-sensitive layers 302 is arranged across the first magneto-sensitive layer 301.

The Hall element 1 illustrated in FIGS. 19A and 19B can improve the sensitivity by applying a large amount of the detection current Is. Furthermore, the electrical resistance of the current paths can be reduced by increasing the current paths of the detection current Is. Therefore, a degree of design concerning the detection current Is can be increased.

FIG. 19A illustrates a configuration in which there are two pairs of the second magneto-sensitive layers 302 across the first magneto-sensitive layer 301, but there may be more than three pairs of the second magneto-sensitive layers 302. FIG. 19B illustrates a configuration including two electromagnetic layer units 30A, but there may be more than three electromagnetic layer units 30A.

### Second Embodiment

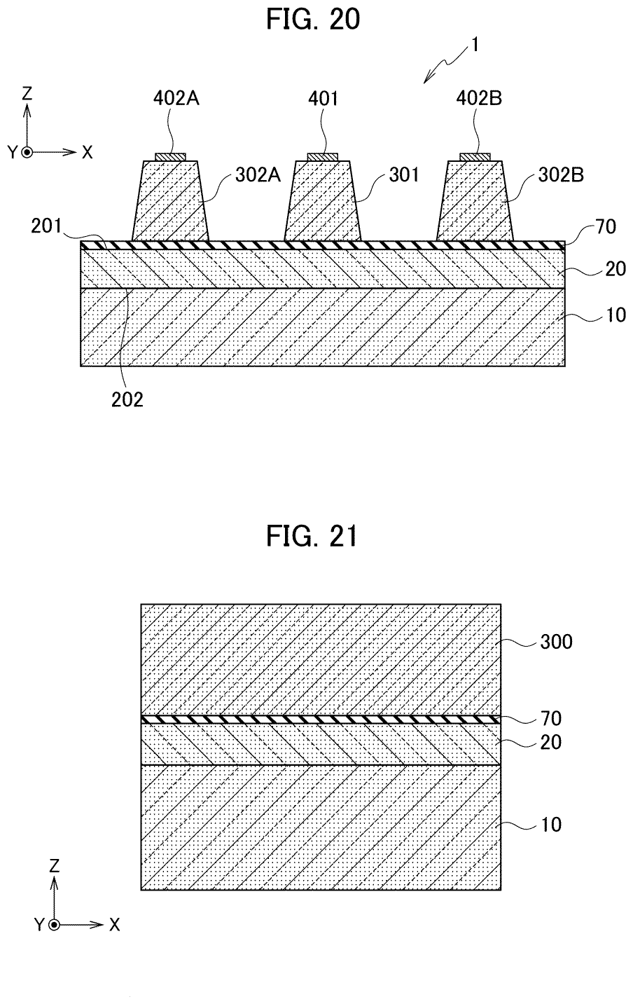

As illustrated in FIG. 20, a Hall element 1 according to a second embodiment differs from the Hall element 1 according to the first embodiment in that it includes a second semiconductor layer 70 disposed between the first and second magneto-sensitive layers 301,302 and the first face 201 of the first semiconductor layer 20. The second semiconductor layer 70 is a semiconductor layer of a material with a composition different from that of the magneto-sensitive layer 30. With regard to other configurations, the second embodiment is similar to the first embodiment illustrated in FIG. 1.

A method of manufacturing the Hall element 1 according to the second embodiment will be described below with reference to the drawings.

First, the first semiconductor layer 20 is formed on the upper face of the substrate 10. Next, as illustrated in FIG. 21, the second semiconductor layer 70 is formed on the first face 201 of the first semiconductor layer 20 by, for example, an epitaxial growth method. Further, the magneto-sensitive layer film 300 is formed on the upper face of the second semiconductor layer 70. The second semiconductor layer 70 is made of a material having a lower etching rate than the magneto-sensitive layer film 300. In other words, the second semiconductor layer 70 has a lower etching rate than the first magneto-sensitive layer 301 and the second magneto-sensitive layer 302.

For example, if the magneto-sensitive layer film 300 is a GaAs film doped with an n-type impurity, the second semiconductor layer 70 may be a phosphorus (P) based compound semiconductor such as InGaP doped with an n-type impurity. The film thickness of the second semiconductor layer 70 is, for example, about 10 nm or less.

Thereafter, the magneto-sensitive layer 30 in a mesa shape, the main electrode 40, and the Hall electrode 50 are formed in the same manner as in the processes described above with reference to FIGS. 7A and 7B to 16A and 16B.

However, unlike the processes described with reference to FIGS. 7A and 7B, the second semiconductor layer 70 functions as an etching stop layer in a process of etching the magneto-sensitive layer film 300 to form the mesa groove 310. Therefore, as illustrated in FIG. 20, the Hall element 1 having a configuration in which the second semiconductor layer 70 is arranged on the first face 201 of the first semiconductor layer 20 is completed. By using the second semiconductor layer 70 as an etching stop layer, the magneto-sensitive layer film 300 can be sufficiently etched without considering that the upper part of the first semiconductor layer 20 is etched by over-etching of the magneto-sensitive layer film 300. This prevents the magneto-sensitive layer film 300 from remaining between the first magneto-sensitive layer 301 and the second magneto-sensitive layer 302 in parallel with the first face 201 of the first semiconductor layer 20.

In the manufacturing process of the Hall element 1 illustrated in FIG. 20, the mesa groove 310 may be formed in two steps of a dry etching method and a wet etching method. For example, after etching the magneto-sensitive layer film 300 to a certain depth using the dry etching method, the magneto-sensitive layer film 300 may be etched until the second semiconductor layer 70 is exposed using the wet etching method. Thus, the etching time can be shortened using the dry etching method, and the second semiconductor layer 70 can be used as an etching stop layer in the wet etching method.

The film thickness of the second semiconductor layer 70 may be as small as, for example, 10 nm. Therefore, the electric resistance of the current flowing through the second semiconductor layer 70 in parallel with the first face 201 of the first semiconductor layer 20 is high, and the flow of the detection current Is through the second semiconductor layer 70 in parallel with the first face 201 can be suppressed. As a result, the current path of the detection current Is flowing between the first magneto-sensitive layer 301 and the second magneto-sensitive layer 302 can be limited to the first semiconductor layer 20. After the magneto-sensitive layer 30 is formed, a part of the second semiconductor layer 70 may be removed so as to expose the first face 201 of the first semiconductor layer 20.

In the description above, a case in which the second semiconductor layer 70 is used as an etching stop layer in the process of forming the magneto-sensitive layer 30 is described. The second semiconductor layer 70 may be used for end point detection (EPD) in etching in a dry etching method.

For example, in the etching process of the magneto-sensitive layer film 300 by the dry etching method, the end point of etching can be detected by detecting a change in the reflectance of light due to a difference in composition elements between the magneto-sensitive layer film 300 and the second semiconductor layer 70. The end point of the etching process can be detected due to a change in the reflectance of light when the magneto-sensitive layer film 300 is a GaAs film, and InGaP film is used as the second semiconductor layer 70.

As described above, in the Hall element 1 according to the second embodiment, the magneto-sensitive layer film 300 does not remain in the remaining region of the first semiconductor layer 20 excluding the region in contact with the magneto-sensitive layer 30 in a mesa shape. Therefore, the detection current Is is prevented from flowing through the magneto-sensitive layer film 300 formed on the surface of the first semiconductor layer 20. The Hall element 1 according to the second embodiment is substantially the same as that of the first embodiment, and the duplicate description thereof is omitted.

### Other Embodiments

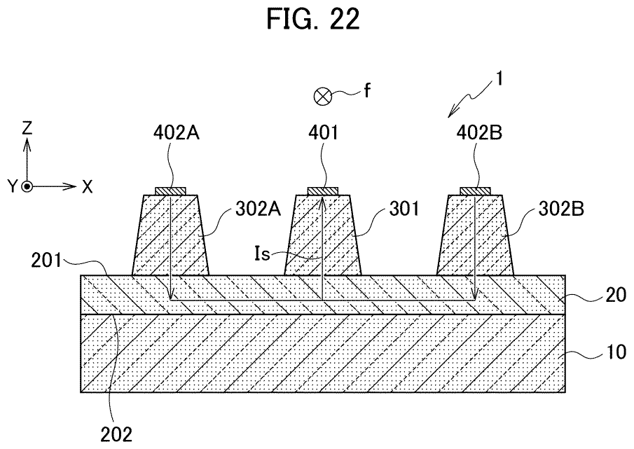

In the description above, a case in which the detection current Is flows from the first magneto-sensitive layer 301 to the two second magneto-sensitive layers 302 arranged on both sides of the first magneto-sensitive layer 301 has been described. However, as illustrated in FIG. 22, the detection current Is may flow from the second magneto-sensitive layer 302 A and the second magneto-sensitive layer 302B to the first magneto-sensitive layer 301. In this case, as illustrated in FIG. 22, the direction of the Lorentz force f is opposite to the direction illustrated in FIG. 2.

The embodiments described above are examples of the present invention. Therefore, the present invention is not limited to the embodiments described above, and it is needless to say that various changes can be made depending on the design or the like, even in the case of an embodiment other than the embodiments described above, without departing from technical ideas of the present invention.

### Supplementary Notes

The technical ideas that can be understood from the present disclosure are described below. It should be noted that, the components described in the supplementary notes are given reference signs of the corresponding components in the embodiments, not with the intention of limiting, but to help understanding. The reference signs are given by way of example to help understanding, and the components described in each supplementary note should not be limited to those indicated by reference signs.

### Supplementary Note 1: First Embodiment, FIG. 1

A Hall element 1 including: a first semiconductor layer 20 that is conductive and defined on both faces by a first face 201 and a second face 202 opposed to each other; and a first magneto-sensitive layer 301 and a second magneto-sensitive layer 302 of a conductive semiconductor in a mesa shape. The first magneto-sensitive layer 301 is arranged above the first face 201 of the first semiconductor layer 20, and has a bottom face opposed to the first face 201. The second magneto-sensitive layer 302 is arranged in a position at a distance from the first magneto-sensitive layer 301 above the first face 201 and has a bottom face opposed to the first face 201. The Hall element 1 according to the supplementary note 1, can provide the Hall element having the magneto-sensitive layer 30 in the mesa shape.

### Supplementary Note 2: First Embodiment, FIG. 1

In the Hall element 1 according to supplementary note 1, in each of the first magneto-sensitive layer 301 and the second magneto-sensitive layer 302, a direction from the bottom face to a top face opposed to the bottom face intersects the first face 201. In the Hall element 1 according to the supplementary note 2, a detection current Is flows through the magneto-sensitive layer 30 in a direction perpendicular to a main surface of a substrate 10. Thus, the Hall element 1 can detect a magnetic field in a direction parallel to the main surface of the substrate 10.

### Supplementary Note 3: First Embodiment, FIG. 1

The Hall element 1 according to supplementary note 1 or 2 further includes a first main electrode 401 arranged on an upper face of the first magneto-sensitive layer 301 and a second main electrode 402 arranged on an upper face of the second magneto-sensitive layer 302. In the Hall element 1 according to the supplementary note 3, the first main electrode 401 is a first end of a current path of a detection current Is and the second main electrode 402 is a second end of the current path of the detection current Is, and the detection current Is flows in a direction perpendicular to the main surface of the substrate 10

### Supplementary Note 4: First Embodiment, FIG. 2

The Hall element 1 according to any one of supplementary notes 1 to 3 further includes a pair of Hall electrodes 50 arranged on the upper face of the first magneto-sensitive layer 301 across the first main electrode 401. In the Hall element 1 according to the supplementary note 4, the Hall electrodes 50 are capable of detecting the Hall output voltage due to a Lorentz force f generated by a magnetic field oriented parallel to the first face 201 and the detection current Is flowing through the first magneto-sensitive layer 301 and the second magneto-sensitive layer 302.

### Supplementary Note 5: First Embodiment, FIG. 1

In the Hall element 1 according to any one of supplementary notes 1 to 4, two second magneto-sensitive layers 302A, 302B of the second magneto-sensitive layer 302 are arranged across the first magneto-sensitive layer 301. In the Hall element 1 according to the supplementary note 5, the presence of two current paths of the detection current Is prevents erroneous detection of the magnetic field passing in the direction perpendicular to the main surface of the substrate 10.

### Supplementary Note 6: First Embodiment, FIG. 1

In the Hall element 1 according to any one of supplementary notes 1 to 5, the bottom face of the first magneto-sensitive layer 301 and the bottom face of the second magneto-sensitive layer 302 contact with the first face 201 of the first semiconductor layer 20. The first magneto-sensitive layer 301 and the second magneto-sensitive layer 302 are in direct contact with the first semiconductor layer 20, so that the electrical resistance of the detection current Is flowing in the direction perpendicular to the first face 201 of the first semiconductor layer 20 can be reduced.

### Supplementary Note 7: First Embodiment, FIG. 5

In the Hall element 1 according to any one of supplementary notes 1 to 6, the first magneto-sensitive layer 301 and the second magneto-sensitive layer 302 are arranged on a top face of a protrusion portion formed on the first face 201 of the first semiconductor layer 20. By forming the magneto-sensitive layer 30 by over-etching so that the protrusion portion is formed on the first face 201 of the first semiconductor layer 20, the magneto-sensitive layer film 300 does not remain in the remaining region of the first face 201 excluding the region in contact with the magneto-sensitive layer 30.

### Supplementary Note 8: Second Embodiment, FIG. 20

The Hall element 1 according to any one of supplementary notes 1 to 5 further includes a second semiconductor layer 70 disposed between the first and second magneto-sensitive layers 301, 302 and the first face 201 of the first semiconductor layer 20, and having a composition different from the first and second magneto-sensitive layers 301, 302. In the Hall element 1 according to the supplementary note 8, the magneto-sensitive layer film 300 does not remain in the region between the first magneto-sensitive layer 301 and the second magneto-sensitive layer 302. Therefore, the detection current Is is prevented from flowing through the magneto-sensitive layer film 300 formed on the surface of the first semiconductor layer 20.

### Supplementary Note 9: Second Embodiment, FIG. 20

In the Hall element 1 according to supplementary note 9, the second semiconductor layer 70 has a lower etching rate than the first magneto-sensitive layer 301 and the second magneto-sensitive layer 302. In the Hall element 1 according to the supplementary note 9, by using the second semiconductor layer 70 as an etching stop layer, it is possible to prevent the magneto-sensitive layer film 300 from remaining on the first face 201 of the first semiconductor layer 20.

### Supplementary Note 10: First Embodiment, FIG. 17

In the Hall element 1 according to any one of supplementary notes 1 to 9, a side face of the first magneto-sensitive layer 301 and a side face of the second magneto-sensitive layer 302 are extend in a direction perpendicular to the first face 201 of the first semiconductor layer 20. In the Hall element 1 according to the supplementary note 10, the size of the Hall element 1 can be reduced.

### Supplementary Note 11: First Embodiment

In the Hall element 1 according to any one of supplementary notes 1 to 10, a material of the magneto-sensitive layer 30 includes a compound semiconductor. In the Hall element 1 according to the supplementary note 11, the material of the magneto-sensitive layer 30 is a compound semiconductor, so that the Hall element 1 with higher sensitivity than when the material of the magneto-sensitive layer 30 is silicon can be obtained with good temperature characteristics having less variation in sensitivity with respect to temperature.

### Supplementary Note 12: First Embodiment

In the Hall element 1 according to supplementary note 11, the material of the magneto-sensitive layer 30 includes gallium arsenide. The material of the magneto-sensitive layer 30 is gallium arsenide of a compound semiconductor, so that the Hall element 1 with high sensitivity and good temperature characteristics can be obtained.

### Supplementary Note 13: First Embodiment

The Hall element 1 according to any one of supplementary notes 1 to 12 further includes an insulating substrate connected to the second face 202 of the first semiconductor layer 20.

1. A Hall element, comprising:
a first semiconductor layer that is conductive and defined on both faces by a first face and a second face opposed to each other;
a first magneto-sensitive layer of a conductive semiconductor in a mesa shape arranged above the first face of the first semiconductor layer and having a bottom face opposed to the first face; and
a second magneto-sensitive layer of a conductive semiconductor in a mesa shape arranged in a position at a distance from the first magneto-sensitive layer above the first face and having a bottom face opposed to the first face.

2. The Hall element according to claim 1, wherein in each of the first magneto-sensitive layer and the second magneto-sensitive layer, a direction from the bottom face to a top face opposed to the bottom face intersects the first face.

3. The Hall element according to claim 1, further comprising:
a first main electrode arranged on an upper face of the first magneto-sensitive layer; and
a second main electrode arranged on an upper face of the second magneto-sensitive layer.

4. The Hall element according to claim 3, further comprising a pair of Hall electrodes arranged on the upper face of the first magneto-sensitive layer across the first main electrode, wherein
the Hall electrodes is capable of detecting a Hall output voltage due to a Lorentz force generated by a magnetic field oriented parallel to the first face of the first semiconductor layer and a detection current flowing through the first magneto-sensitive layer and the second magneto-sensitive layer.

5. The Hall element according to claim 1, wherein two second magneto-sensitive layers of the second magneto-sensitive layer are arranged across the first magneto-sensitive layer.

6. The Hall element according to claim 1, wherein the bottom face of the first magneto-sensitive layer and the bottom face of the second magneto-sensitive layer contact with the first face of the first semiconductor layer.

7. The Hall element according to claim 6, wherein the first magneto-sensitive layer and the second magneto-sensitive layer are arranged on a top face of a protrusion portion formed on the first face of the first semiconductor layer.

8. The Hall element according to claim 1, further comprising a second semiconductor layer disposed between the first and second magneto-sensitive layers and the first face of the first semiconductor layer, and having a composition different from the first and second magneto-sensitive layers.

9. The Hall element according to claim 8, wherein the second semiconductor layer has a lower etching rate than the first magneto-sensitive layer and the second magneto-sensitive layer.

10. The Hall element according to claim 1, wherein a side face of the first magneto-sensitive layer and a side face of the second magneto-sensitive layer extend in a direction perpendicular to the first face of the first semiconductor layer.

11. The Hall element according to claim 1, wherein a material of the first magneto-sensitive layer and the second magneto-sensitive layer includes a compound semiconductor.

12. The Hall element according to claim 11, wherein the material of the first magneto-sensitive layer and the second magneto-sensitive layer includes a gallium arsenide.

13. The Hall element according to claim 1, further comprising an insulating substrate connected to the second face of the first semiconductor layer.
